(19) United States
(12) Patent Application Publication
(10) Pub. No.: US 2026/0063335 A1
(43) Pub. Date: Mar. 5, 2026

(54) CONTROL APPARATUS FOR VEHICLE

(71) Applicant: HYUNDAI MOBIS CO., LTD., Seoul (KR)

(72) Inventor: Yong Whan KIM, Yongin-si (KR)

(73) Assignee: HYUNDAI MOBIS CO., LTD., Seoul (KR)

(21) Appl. No.: 19/249,175

(22) Filed: Jun. 25, 2025

(30) Foreign Application Priority Data
Aug. 28, 2024 (KR) 10-2024-0115603

(51) Int. Cl. F25B 9/04; B60K 35/22; H05K 7/20

(52) U.S. Cl. CPC F25B 9/04; H05K 7/20863; B60K 35/22; B60K 2360/164; B60K 2360/42

(57) ABSTRACT

Disclosed is a control apparatus for a vehicle. According to an embodiment of the present disclosure, there is provided a control apparatus for a vehicle comprising a housing having an accommodation space therein and including an opening formed on at least one surface, a board disposed in the housing and including heating elements, a cooling fan inducing convection of air in the accommodation space of the housing and covering the opening, a compression nozzle including an adhesion portion being in close contact with the cooling fan and a pressure portion suctioning and compressing air flowing from the cooling fan, a vortex tube suctioning compressed air from the compression nozzle, separating the air into hot air and cold air, discharging the hot air out of the housing, and discharging the cold air into the housing, a temperature sensor measuring one or more of temperature of the inside of the accommodation space or temperature of the heating elements, and a controller controlling a speed of the cooling fan on the basis of a signal transmitted from the temperature sensor.

### CROSS-REFERENCE TO RELATED APPLICATION

This application claims the benefit of and priority to Korean Patent Application No. 10-2024-0115603, filed on Aug. 28, 2024, the entire disclosure(s) of which is hereby incorporated herein by reference in its entirety.

### TECHNICAL FIELD

The present disclosure relates to a control apparatus for a vehicle. In more detail, the present disclosure relates to a control apparatus for a vehicle that improves heat dissipation performance using a vortex tube.

### BACKGROUND

The description of this part only provides the background information of the present disclosure without configuring the related art.

An infotainment system is an integrated system of ‘information’ that refers to necessary information such as driving and navigation and ‘entertainment’ that refers to various amusements and use-friendly functions.

An infotainment system includes a navigation, an audio, and a video in a vehicle. With the popularization of smartphones and tablets and development of IT, an infotainment system is expanding its scope to include mobile offices, smart navigation, vehicle tracking, gesture recognition, vehicle-to-vehicle (V2V) communication, and cloud access.

Vehicle control apparatuses such as an electronic control unit (ECU), a microcontroller unit (MCU) are mounted in vehicles to control an infotainment system.

Recently, the demand for high-performance control apparatuses is increasing due to technological developments in autonomous driving, wireless communication, and other fields. A high-performance vehicle control apparatus may include a housing, and a printed circuit board (PCB) and a central processing unit (CPU) accommodated in the housing.

Multiple electronic parts (electronic control elements) for controlling a vehicle and power supply are mounted on the printed circuit board. Accordingly, the control apparatus itself generates heat and such an increase of temperature causes performance degradation and element damage.

Control apparatuses for a vehicle of the related art solved the problem of heat generation using a cooling fan and a heatsink. This method uses external air lower in temperature than the inside of a control apparatus and has a difficulty in maintaining a temperature lower than the outside of a control apparatus, so it has a limitation in effect. A refrigerant may be used to solve this problem, but there is a problem in that it is difficult to apply a refrigerant to an in-vehicle infotainment system and the manufacturing cost increases.

### SUMMARY

A control apparatus for a vehicle according to an embodiment has a main object that provides an apparatus and method of compressing air flowing from a cooling fan using a compression nozzle and providing the compressed air to a vortex tube.

A control apparatus for a vehicle according to an embodiment has a main object that provides a control apparatus for a vehicle having improved heat dissipation performance using a vortex tube.

The objects of the present disclosure are not limited to the objects described above and other objects will be clearly understood by those skilled in the art from the following description.

### Solution to Problem

According to an embodiment of the present disclosure, there is provided a control apparatus for a vehicle comprising a housing having an accommodation space therein and including an opening formed on at least one surface, a board disposed in the housing and including heating elements, a cooling fan inducing convection of air in the accommodation space of the housing and covering the opening, a compression nozzle including an adhesion portion being in close contact with the cooling fan and a pressure portion suctioning and compressing air flowing from the cooling fan, a vortex tube suctioning compressed air from the compression nozzle, separating the air into hot air and cold air, discharging the hot air out of the housing, and discharging the cold air into the housing, a temperature sensor measuring one or more of temperature of the inside of the accommodation space or temperature of the heating elements, and a controller controlling a speed of the cooling fan on the basis of a signal transmitted from the temperature sensor.

### Advantageous Effects

According to an embodiment, there is an effect that it is possible to compress air flowing from a cooling fan using a compression nozzle and provide the compressed air to a vortex tube.

According to an embodiment, the control apparatus for a vehicle according to an embodiment has an effect of improving the heat dissipation performance of the control apparatus for a vehicle using a vortex tube.

### BRIEF DESCRIPTION OF THE DRAWINGS

FIG. 1 is a block diagram showing the configuration of a control apparatus for a vehicle according to an embodiment of the present disclosure.

FIG. 2 is a block diagram showing the configuration of a control apparatus for a vehicle additionally having a cold air supply line according to an embodiment of the present disclosure.

FIG. 3 is a block diagram showing the configuration of a control apparatus for a vehicle additionally having a pressure sensor according to an embodiment of the present disclosure.

### DETAILED DESCRIPTION

Hereinafter, some embodiments of the present disclosure will be described in detail with reference to exemplary drawings. Note that when components in each drawing are denoted by reference numerals, the same components are denoted by the same numerals as much as possible even if they are denoted on different drawings. In addition, in describing the present disclosure, if it is determined that a specific description of a related known configuration or function may obscure the gist of the present disclosure, the detailed description thereof will be omitted.

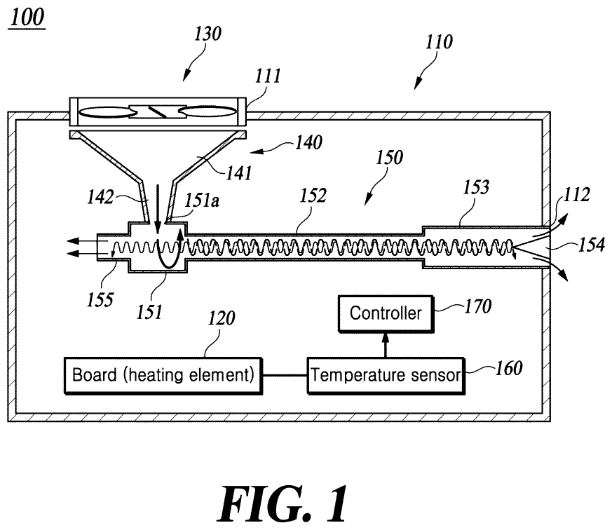

In describing components of embodiments of the present disclosure, reference numerals such as first, second, i), ii), a), and b) may be used. These symbols are only used to distinguish the components from other components, and the nature, sequence, order, or the like of that component is not limited by the symbols. Throughout the specification, when it is stated that a certain portion “includes” or “comprises” a specific component, it shall be understood that, unless explicitly otherwise specified, this does not exclude other components but may further include additional components. FIG. 1 is a cross-sectional view showing the configuration of a control apparatus for a vehicle according to an embodiment of the present disclosure.

Referring to FIG. 1, a control apparatus for a vehicle may include all or some of a housing 110, a board 120, a cooling fan 130, a compression nozzle 140, a vortex tube 150, a temperature sensor 160, and a controller 170.

The housing 110 forms the external appearance of the control apparatus 100 for a vehicle. An internal space may be formed in the housing 110. The board 120 may be disposed in the internal space of the housing 110. The housing 110 may include an opening 111 formed on at least one surface.

A heat dissipation member (not shown) for discharging heat generated from heating elements may be disposed in the housing 110. The heat dissipation member may include a heat sink composed of a heat dissipation fin structure. The heat dissipation member may be replaced with another type of heat dissipation member such as a heat pipe. However, this is an exemplary configuration and the present disclosure is not necessarily limited thereto.

The housing 110 may be formed using a part with excellent rigidity such as a Steel Electrogalvanized Cold-rolled Coil (SECC) and may be manufactured using a pressing process. In this case, the pressing process refers to a process that machines a material using a press and forms or cuts a material by applying pressure. This is exemplary description of function and the present disclosure is not necessarily limited thereto.

The board 120 may be disposed in the internal space of the housing 110. The board 120 can control the function of an infotainment system included in a vehicle.

The board 120 can process various signals such as audio input, navigation signals, and communication data input from the inside and the outside of a vehicle. The board 120 can control various functions such as an audio system, a video display, a navigation system, a communication module, and a touch screen on the basis of processed information. However, this is an exemplary configuration and the present disclosure is not necessarily limited thereto.

The board 120 may include various devices. The various devices perform different functions and operate through interaction. The board 120 may include a kind of printed circuit board PCB on which electronic devices (not shown) such as a diode are mounted.

A microcontroller, a microprocessor, a memory, an Analog-Digital Converter (ADC), a Digital-Analog Converter (DAC), a power management circuit, a signal processing circuit, and the like may be included in the board 120. However, this is an exemplary configuration and the present disclosure is not necessarily limited thereto.

Control elements may be mounted in an area of a surface of the board 120. The control elements include at least one or more heating elements. The heating elements may include a central processing unit (CPU), a graphic processing unit (GPU), a sensor interface, and the like.

The cooling fan 130 can induce convection of air in an accommodation space of the housing 110.

The cooling fan 130 can cover the opening 111. Convention of air in the accommodation space can be achieved by introducing external air into the accommodation space using the cooling fan 130 or discharging the air in the accommodation space out of the housing 110 using the cooling fan 130.

The compression nozzle 140 can suction and compress air flowing from the cooling fan 130. Additional attachment of a compressor causes problems such as a spatial limitation, additional power consumption, complexity of installation, and an increase of costs due to the features of an infotainment system, so it is practically difficult to install a compressor. Accordingly, in an embodiment of the present disclosure, it is possible to produce compressed air from the air flowing from the cooling fan 130 using the compression nozzle 140 and then supply the compressed air to the vortex tube 150.

The compression nozzle 140 may include all or some of an adhesion portion 141 and a pressure portion 142.

The adhesion portion 141 may be disposed in close contact with the cooling fan 130. For example, it can be brought in close contact using a screw, an adhesive, bolt/nut, and the like. In detail, when the adhesion portion is coupled using a screw, threads are formed on the outer circumferential surface of the adhesion portion 141 and threads are formed on the inner circumferential surface of the cooling fan 130, whereby the adhesion portion 141 and the cooling fan 130 can be engaged and coupled to each other. However, this is an exemplary configuration and the present disclosure is not necessarily limited thereto.

The adhesion portion 141 may include an upper end portion corresponding to the cooling fan 130 and a lower end portion of which the inner diameter gradually decreases inwardly compared to the upper end portion of the housing 110. The upper end portion is configured to be in close contact with the inner side of the cooling fan 130, so it is possible to effectively accommodate air flowing from the cooling fan 130. The lower portion induces smooth flow of air and may be configured such that the inner diameter gradually decreases to transmit compressed air to the pressure portion 142.

The adhesion portion 141 may be configured to have an inner diameter at least larger than the inner diameter of the cooling fan 130 to suction air discharged from the cooling fan 130. Accordingly, it is possible to efficiently absorb all the air flowing from the cooling fan 130 and transmit the air to the vortex tube 150 without leakage of the air.

The adhesion portion 141 may further include a blocking member (not shown) to prevent leakage of air that is discharged from the cooling fan 130. The blocking member may be configured to completely seal the gap between the adhesion portion 141 and the cooling fan 130 so that air is prevented from leaking outside.

The blocking member (not shown) may be configured using an elastic material such as rubber or silicone. However, this is an exemplary configuration and the present disclosure is not necessarily limited thereto.

The pressure portion 142 can suction and compress air flowing from the cooling fan 130. In detail, the pressure portion 142 is formed such that the inner diameter at the end of the pressure portion 142 connected with a vortex generation 151 is smaller than the inner diameter of the upper end portion in which air flows, so the pressure in the compression nozzle can be increased. Inflow air passes through a passage that becomes narrow, so pressure increases, and accordingly, the flow speed of the air can be increased and the air can be effectively compressed.

The vortex tube 150 can separate compressed air into hot air and cold air. In this case, the vortex tube 150 refers to a tube that can produce ultra-low temperature air (over −60° C.) within a very short time by supplying compressed air (3˜10 kg/cm²) without using a refrigerant, electricity, or a chemical by spirally rotating air.

The vortex tube 150 can discharge hot air out of the housing 110. The vortex tube 150 can discharge cold air into the housing 110. The discharged cold air can decrease the temperature of the inside of the housing 110.

The vortex tube 150 may include all or some of a vortex generation 151, a body 152, a hot air vent 153, a control valve 154, and a cold air vent 155.

The vortex generation 151 may include a mounting hole 151a formed through a surface of the vortex generation 151 to be able to be coupled to the pressure portion 142. The pressure portion 142 may be coupled through the mounting hole 151a.

The pressure portion 142 and the mounting portion 151a may be configured in an integral type or a separate type. When they are configured in a separate type, they can be coupled using a screw, an adhesive, bolt/nut, and the like. In detail, when they are coupled using a screw, threads are formed on the outer circumferential surface of the pressure portion 142 and threads are formed on the inner circumferential surface of the mounting hole 151a, whereby the pressure portion 142 and the mounting hole 151a can be engaged and coupled to each other. However, this is an exemplary configuration and the present disclosure is not necessarily limited thereto.

The vortex generation 151 may be configured to suction compressed air from the pressure portion 142 and form a vortex from the suctioned compressed air. The air flowing from the pressure portion 142 hits against lower portion of the vortex generation 151 and rotates at a high speed, so it can form a vortex.

The vortex can move toward the body 152 from the vortex generation 151. The vortex can move along the inside of the body 152. Hot air and cold air can be separated by a centrifugal force. Hot air positioned outside the vortex can move toward the hot air vent 153 along the inner wall of the body 152. Cold air is positioned inside the vortex and can move along the center of the body 152.

The body 152 may be disposed at a side of the vortex generation 151. The body 152 may be configured to be long such that rotating air moves toward a side of the vortex generation 151.

The hot air vent 153 may be configured such that rotating hot air at the outer side of rotating air is discharged toward a side of the vortex generation 154 along the inner wall of the body 152.

The hot air vent 153 may be coupled to a vent hole 112 formed through a surface of the housing 110. The hot air vent 153 can discharge hot air out of the housing 110 using the vent hole 112.

The control valve 154 may be disposed at a side of the hot air vent 153. The control valve can adjust the amount of hot air that is discharged out of the housing 110.

The cold air vent 155 may be disposed at another side of the vortex generation 151. The movement direction of hot air not discharged from the hot air vent 153 can be changed by the control valve 154. In detail, hot air not discharged from the hot air vent 153 rotates in the opposite direction to the movement direction of hot air by hitting against the control valve 152 and can move toward the center of the body 152.

As the hot air of which the movement direction is changed moves toward the center of the body 152, pressure relatively decreases and heat is lost, so cold air can be produced. The cold air moves toward another side of the vortex generation 151. The cold air vent 155 may be configured to discharge cold air to another side of the vortex generation 151.

The cold air discharged from the cold air vent 155 can be distributed in the housing 110. It is possible to remove heat generated from heating elements using the cold air distributed in the housing 110.

The vortex tube 150 may be formed in a circular tube shape. The circular tube structure enables compressed air to effectively produce a vortex by optimizing the rotation motion of air. Accordingly, the vortex generation, the body, the hot air vent, and the cod air bent may be configured in a circular tube shape. However, this is an exemplary configuration and the present disclosure is not necessarily limited thereto.

The temperature sensor 160 can measure one or more of the temperature of the inside of the accommodation space or the temperature of the heating elements.

The controller 170 can adjust the speed of the cooling fan 130. The controller 170 can control the speed of the cooling fan 130 on the basis of a signal transmitted from the temperature sensor. The controller 170 can reduce power consumption by stopping the cooling fan 130 when temperature is under a predetermined level. The controller 170 according to an exemplary embodiment of the present disclosure may be a hardware device implemented by various electronic circuits (e.g., computer, microprocessor, CPU, ASIC, circuitry, logic circuits, etc.). The controller 170 may be implemented by a non-transitory memory storing, e.g., a program(s), software instructions reproducing algorithms, etc., which, when executed, performs various functions described hereinafter, and a processor configured to execute the program(s), software instructions reproducing algorithms, etc. Herein, the memory and the processor may be implemented as separate semiconductor circuits. Alternatively, the memory and the processor may be implemented as a single integrated semiconductor circuit. The processor may embody one or more processor(s).

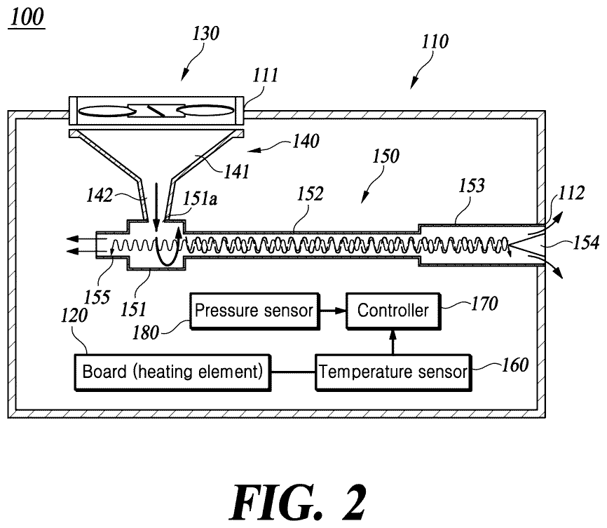

FIG. 2 is a cross-sectional view showing the configuration of a control apparatus for a vehicle additionally having a cold air supply line according to an embodiment of the present disclosure.

Referring to FIG. 2, the cold air vent 155 may further include a cold air supply line 156.

The cold air supply line 156 may be connected with the cold air vent 155. The cold air supply line 156 can supply cold air discharged from the cold air vent 155. The cold air supply line 156 may be disposed adjacent to heating elements. The cold air supply line 156 can directly remove heat generated from the heating elements using cold air discharged from the cold air vent 155.

The cold air supply line 156 may be a structure such as a tube or a pipe extending to supply cold air to a place or a configuration that requires cold air. However, this is an exemplary configuration and the present disclosure is not necessarily limited thereto.

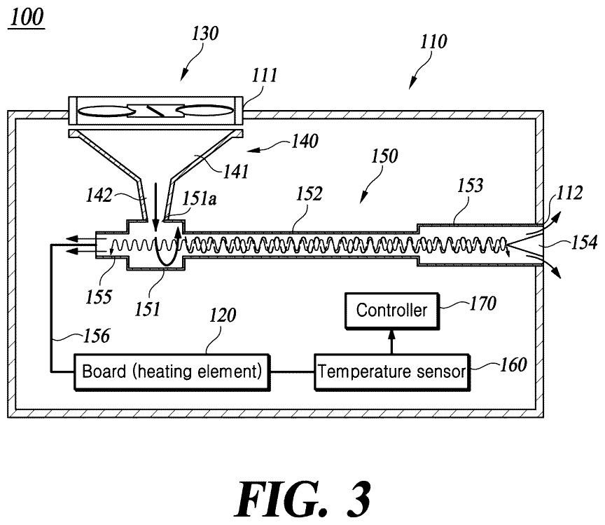

FIG. 3 is a cross-sectional view showing the configuration of a control apparatus for a vehicle additionally having a pressure sensor according to an embodiment of the present disclosure.

Referring to FIG. 3, the control apparatus 100 for a vehicle may further include a pressure sensor 180. The pressure sensor 180 may be disposed in the compression nozzle 140. The pressure sensor 180 can measure the pressure of the compressed air in the compression nozzle 140.

The controller can monitor the pressure of the compression nozzle 140 on the basis of a signal transmitted from the pressure sensor 180. Accordingly, when the pressure of the compression nozzle 140 does not reach or exceeds a reference level, the controller can control the speed of the cooling fan 130 or notify air leakage at the compression nozzle 140. In detail, the controller can sense the case in which the pressure portion 142 and the vortex generation 151 are not in close contact or the adhesion portion 141 and the cooling fan 130 are not is complete close contact, and can maintain a state optimized for producing compressed air.

Each element of the apparatus or method in accordance with the present invention may be implemented in hardware or software, or a combination of hardware and software. The functions of the respective elements may be implemented in software, and a microprocessor may be implemented to execute the software functions corresponding to the respective elements.

Various embodiments of the systems and techniques described herein may be realized in digital electronic circuitry, integrated circuitry, field programmable gate arrays (FPGAs), application specific integrated circuits (ASICs), computer hardware, firmware, software, and/or combinations thereof. These various embodiments may include implementation in one or more computer programs that are executable on a programmable system.

The programmable system includes at least one programmable processor (which may be a special-purpose processor or a general-purpose processor) coupled to receive data and commands from, and to transmit data and commands to, storage systems, at least one input device, and at least one output device.

Computer programs (also known as programs, software, software applications, or code) include commands for a programmable processor and are stored in a “computer readable recording medium”.

The computer-readable recording medium includes all kinds of recording devices in which data that may be read by a computer system is stored. The computer-readable recording medium may be a non-volatile or non-transitory medium such as ROM, CD-ROM, magnetic tape, floppy disk, memory card, hard disk, magneto-optical disk, or storage device, and may further include transitory medium such as data transmission medium. In addition, the computer-readable recording medium may be distributed in a network-connected computer system, and the computer-readable code may be stored and executed in a distributed manner.

In the flowcharts/timing diagrams of the present specification, each process is described as being executed sequentially, however, this is merely an example of the technical idea of an embodiment of the present disclosure.

In other words, the flowcharts/timing diagrams are not limited to a chronological order, as those skilled in the art may make various modifications and variations to the sequence of the flowchart/timing diagram or to perform one or more of the processes in parallel without departing from the essential characteristics of the embodiments of the present disclosure.

The foregoing descriptions are merely illustrative of the technical idea of the present embodiment, and various modifications and variations may be made by those skilled in the art without departing from the essential characteristics of the present embodiment. Therefore, the present embodiments are not intended to limit the technical idea of the present embodiments, but are intended to be illustrative, and the scope of the technical idea of this embodiment is not limited by these embodiments. The protection scope of the present embodiment is to be construed according to the following claims, and all technical ideas within the scope equivalent thereto are construed as being included in the scope of rights of the present embodiment.

### DESCRIPTION OF SYMBOLS

100 control apparatus for vehicle, 110 housing, 120 board, 130 cooling fan, 140 compression nozzle, 150 vortex tube, 160 temperature sensor, 170 controller, 180 pressure sensor

What is claimed is:

1. A control apparatus for a vehicle, comprising:
a housing having an accommodation space therein and including an opening formed on at least one surface;
a board disposed in the housing and including heating elements;
a cooling fan inducing convection of air in the accommodation space of the housing and covering the opening;
a compression nozzle including an adhesion portion being in close contact with the cooling fan and a pressure portion suctioning and compressing air flowing from the cooling fan;
a vortex tube suctioning compressed air from the compression nozzle, separating the air into hot air and cold air, discharging the hot air out of the housing, and discharging the cold air into the housing;
a temperature sensor measuring one or more of temperature of the inside of the accommodation space or temperature of the heating elements; and
a controller controlling a speed of the cooling fan based on a signal transmitted from the temperature sensor.

2. The control apparatus of claim 1, wherein the adhesion portion includes an upper end portion corresponding to the cooling fan and a lower end portion of which an inner diameter gradually decreases toward the inside of the housing compared to the upper end portion; and the pressure portion extends toward the inside of the housing from the lower end portion.

3. The control apparatus of claim 2, wherein the adhesion portion is configured to have an inner diameter at least larger than an inner diameter of the cooling fan to suction air discharged from the cooling fan.

4. The control apparatus of claim 2, wherein the adhesion portion further includes a blocking member to prevent leakage of air discharged from the cooling fan.

5. The control apparatus of claim 2, wherein the vortex tube includes:
a vortex generation configured to suction compressed air from the pressure portion and form a vortex from the suctioned compressed air;
a body disposed at a side of the vortex generation and configured to enable the vortex air to move to a side of the vortex generation;
a hot air vent configured such that hot air rotating at an outer side of the vortex air is discharged toward a side of the vortex generation along an inner wall of the body;
a control valve disposed at a side of the hot air vent and adjusting the amount of the hot air discharged out of the housing; and
a cold air vent disposed at another side of the vortex generation, configured to produce cold air from hot air not discharged from the hot air vent by losing heat through the control valve, and configured to discharge the produced cold air toward another side of the vortex generation.

6. The control apparatus of claim 5, wherein the vortex generation includes a mounting hole formed through a surface of the vortex generation to be coupled to the pressure portion.

7. The control apparatus of claim 5, wherein the hot air vent is coupled to a vent hole formed through a surface of the housing and discharges the hot air out of the housing.

8. The control apparatus of claim 1, wherein the vortex tube is configured in a circular tube shape.

9. The control apparatus of claim 5, further comprising a cold air supply line connected with the cold air vent and supplying the cold air discharged from the cold air vent,
wherein the cold air supply line is disposed adjacent to the heating elements and removes heat generated from the heating elements.

10. The control apparatus of claim 1, further comprising a pressure sensor disposed in the compression nozzle and measuring pressure of compressed air,
wherein the controller monitors pressure of the compression nozzle based on a signal transmitted from the pressure sensor.
